(19) United States
(12) Patent Application Publication
(10) Pub. No.: US 2004/0013008 A1
(43) Pub. Date: Jan. 22, 2004

(54) Recording/reproducing apparatus and recording/reproducing method

(76) Inventor: Yoichi Kondo, Saijo-shi (JP)

Correspondence Address: SHERIDAN ROSS PC, 1560 BROADWAY, SUITE 1200, DENVER, CO, 80202

(21) Appl. No.: 10/333,545

(22) PCT Filed: Apr. 30, 2002
(86) PCT No.: PCT/JP02/04342

(30) Foreign Application Priority Data
May 11, 2001 (JP) 2001-142176

(51) Int. Cl. G11C 29/00

(52) U.S. Cl. 365/200

(57) ABSTRACT

A recording and reproducing apparatus and a recording and reproducing method are proposed which can maintain a disk medium always in a state with a few fragmented files without forcing a burden upon a user. The recording and reproducing apparatus according to the present invention comprises a file transfer managing unit which detects a fragmented file from among files which are stored in a disk apparatus and moves the file using a data buffer such that the fragmented file will be defragmented, and during reproduction, when the file transfer managing unit detects fragmentation of a file to be reproduced, the file transfer managing unit automatically moves the file such that the fragmented file will be defragmented.

### TECHNICAL FIELD

The present invention relates to an apparatus for and a method of recording and reproducing a video signal or an audio signal.

### BACKGROUND ART

A prior art recording and reproducing apparatus has had features of a high-speed jump-to-scene function, a high-speed edit function and the like which utilize a highly advanced random access capability of a disk storage medium which is used as a main storage medium.

However, in the event that repeated recording, adding, deleting and editing of contents create a discontinuous area on a recording medium, the data transfer rate locally slows down when a head moves over a discontinuous point and waits to rotate after moving over a discontinuous point. This not only invites a deterioration in system capability but also results in such problems like a missing frame and a noise in video and audio during recording and reproduction of a content such as video and audio which demands a certain band.

Proposed to solve these problems is file defragment processing according to which a file recorded scatteringly on a disk medium is re-stored in a continuous area, as described in Japanese Patent Application Laid-Open Gazette No. H7-78097.

Still, since the file defragment processing takes a considerable amount of time, once an apparatus starts the file defragment processing, the apparatus can not execute other processing for a long time.

In addition, since a user is required to manage an elapsed time, a status and the like to execute the file defragment processing, the user is subjected to a burden.

Further, not only when the file defragment processing is executed in accordance with a user's judgment but even in the event that the file defragment processing is automatic executed by automatically detecting percentage of fragmented files, the file defragment processing takes place after fragmentation has already progressed to a certain extent. Hence, it is not possible to keep a disk medium always in a stable state with less fragmentation of files.

The present invention is for solving these problems with the prior art, and accordingly, aims at providing a recording and reproducing apparatus and a recording and reproducing method which do not invite a problem that other processing can not be executed for a long time during execution of the file defragment processing.

### DISCLOSURE OF INVENTION

To achieve the object described above, a recording and reproducing apparatus according to the present invention comprises:

a disk apparatus which stores data as a file;

a data buffer which temporarily holds data read out from the disk apparatus;

a data outputting unit which outputs data read out from the data buffer; and

a file transfer managing unit which detects a fragmented file from among files which are stored in the disk apparatus, checks a state of a free area within the disk apparatus, and moves the file using the data buffer such that the fragmented file will be defragmented, wherein

when the file transfer managing unit detects fragmentation of a file to be reproduced during reproduction, the file transfer managing unit automatically moves the file such that the fragmented file will be defragmented.

Hence, it is possible to perform processing for defragmenting fragmented files in the background during reproduction.

In a recording and reproducing apparatus according to other aspect of the present invention, during reproduction, the file transfer managing unit ensures that a file which is held in the data buffer for reproduction and which is to be moved will not be overwritten until the file has been moved.

Hence, it is possible to protect a file for reproduction without fail which is stored in the data buffer.

In the recording and reproducing apparatus according to another aspect of the present invention, upon stop of reproduction, the file transfer managing unit interrupts file moving for defragmenting the fragmented file.

This allows to perform processing for defragmenting fragmented files only during a reproducing operation.

In the recording and reproducing apparatus according to another aspect of the present invention, the disk apparatus is a disk apparatus which can be removed from the recording and reproducing apparatus.

The disk apparatus is thus not limited to a fixed HDD (Hard Disk Drive) for example, which permits to provide a versatile recording and reproducing apparatus.

In the recording and reproducing apparatus according to another aspect of the present invention, the file transfer managing unit monitors the number of processing requests for recording or reproduction, and when the number of the processing requests exceeds a certain number, the file transfer managing unit interrupts file moving for defragmenting the fragmented file.

Hence, it is possible to perform processing for defragmenting fragmented files without disturbing normal recording and reproducing operations.

In the recording and reproducing apparatus according to another aspect of the present invention, the file transfer managing unit monitors an information volume of processing requests for recording or reproduction, and when the information volume of the processing requests which have not been executed yet exceeds a certain value, the file transfer managing unit interrupts file moving for defragmenting the fragmented file.

Hence, it is possible to perform processing for defragmenting fragmented files without disturbing normal recording and reproducing operations.

In the recording and reproducing apparatus according to another aspect of the present invention, the file transfer managing unit monitors a byte count of readable byte buffered in the data buffer, and when the byte count of readable byte is smaller than a certain count, the file transfer managing unit interrupts file moving for defragmenting the fragmented file.

Hence, it is possible to perform processing for defragmenting fragmented files without disturbing normal recording and reproducing operations.

In the recording and reproducing apparatus according to another aspect of the present invention, when file moving for defragmenting the fragmented file is interrupted, the file transfer managing unit secures on the disk apparatus a free area which is necessary for defragmenting the fragmented file in relation to the file such that the secured area will not be used during recording.

This accelerates the processing and prevents occurrence of new fragmentation, upon resumption of the file defragment processing.

In a recording and reproducing apparatus according to another aspect of the present invention, the file transfer managing unit releases the secured area upon issuance of a new recording request and detection of a shortage of a demanded recording area.

Hence, it is possible to perform processing for defragmenting fragmented files without disturbing normal recording and reproducing operations.

In a recording and reproducing apparatus according to yet another aspect of the present invention, the file transfer managing unit detects a change made to a file which is associated with the secured area and releases the secured area.

Hence, it is possible to perform processing for defragmenting fragmented files without disturbing normal recording and reproducing operations.

A recording and reproducing method of recording and reproducing a video signal or an audio signal comprises:

a step of inputting a reproduction instruction;

a reading step of reading data which are stored as a file in a disk apparatus;

a buffering step of holding read data in a data buffer;

a data outputting step of outputting data read out from the data buffer; and

a defragmenting step of, upon detection of a fragmented file from among files which are stored in the data buffer, automatically moving the file such that fragmented file will be defragmented.

Hence, it is possible to perform processing for defragmenting fragmented files in the background during reproduction.

The recording and reproducing method according to another aspect of the present invention comprises a step of ensuring that a file which is held in the data buffer for reproduction and which is to be moved will not be overwritten until the file has been moved during reproduction.

Hence, it is possible to protect a file for reproduction without fail which is stored in the data buffer.

The recording and reproducing method according to another aspect of the present invention comprises a step at which upon stop of reproduction, the file transfer managing unit interrupts file moving for defragmenting the fragmented file.

This allows to perform processing for defragmenting fragmented files only during a reproducing operation.

The recording and reproducing method according to another aspect of the present invention comprises a step of monitoring the number of processing requests for recording or reproduction, and interrupting file moving for defragmenting the fragmented file when the number of the processing requests exceeds a certain number.

Hence, it is possible to perform processing for defragmenting fragmented files without disturbing normal recording and reproducing operations.

The recording and reproducing method according to another aspect of the present invention comprises a step of monitoring an information volume of processing requests for recording or reproduction, and interrupting file moving for defragmenting the fragmented file when the information volume of the processing requests which have not been executed yet exceeds a certain value.

Hence, it is possible to perform processing for defragmenting fragmented files without disturbing normal recording and reproducing operations.

The recording and reproducing method according to another aspect of the present invention comprises a step of monitoring a byte count of readable byte buffered in the data buffer, and interrupting file moving for defragmenting the fragmented file when the byte count of readable byte is smaller than a certain count.

Hence, it is possible to perform processing for defragmenting fragmented files without disturbing normal recording and reproducing operations.

The recording and reproducing method according to another aspect of the present invention comprises a step of securing on the disk apparatus a free area which is necessary for defragmenting the fragmented file in relation to the file when file moving for defragmenting the fragmented file is interrupted, such that the secured area will not be used during recording.

This accelerates the processing and prevents occurrence of new fragmentation, upon resumption of file defragment processing.

The recording and reproducing method according to a different aspect of the present invention comprises a step of releasing the secured area upon issuance of a new recording request and detection of a shortage of a demanded recording area.

Hence, it is possible to perform processing for defragmenting fragmented files without disturbing normal recording and reproducing operations.

The recording and reproducing method according to yet another aspect of the present invention comprises a step of detecting a change made to a file which is associated with the secured area and releasing the secured area.

Hence, it is possible to perform processing for defragmenting fragmented files without disturbing normal recording and reproducing operations.

The present invention provides an effect that it is possible to realize an apparatus for and a method of recording and reproducing a video signal or an audio signal, which execute the file defragment processing in the background during a reproducing operation to thereby eliminate a burden upon a user and maintain a disk medium always in a stable state with less fragmentation of files.

While the novel features of the present invention are those particularly pointed out in the attached CLAIMS, both the structure and the content of the present invention as well as other objects and features of the present invention will be well understood and evaluated from the following detained description when taken in conjunction with the correlated drawings.

### BRIEF DESCRIPTION OF DRAWINGS

FIG. 1 is a block diagram showing a structure of a recording and reproducing apparatus according to a preferred embodiment 1 of the present invention;

FIG. 2 is an explanatory diagram showing an internal structure of a file transfer managing unit 5;

FIG. 3 is an explanatory diagram showing an internal structure of fragmented file detection information 43;

FIG. 4 is an explanatory diagram showing a state inside a data buffer 1 as it is during a reproducing operation and file movement;

FIG. 5 is a flow chart showing an operation between the data buffer 1 and a data outputting unit 4;

FIG. 6 is a flow chart showing an operation between a disk apparatus 2 and the data buffer 1;

FIG. 7 is an explanatory diagram showing a condition within disk apparatus 2 until defragmentation;

FIG. 8 is a flow chart showing a file moving interruption judging operation;

FIG. 9 is an explanatory diagram showing an internal structure of an interrupted file information list 44;

FIG. 10 is an explanatory diagram showing a condition within disk apparatus 2 until securing of an area for continued file moving in response to a file moving interruption;

FIG. 11 is a flow chart showing a secured area release judging (detection of a recording capacity shortage) operation;

FIG. 12 is a flow chart showing a secured area release judging (change of an interrupted file) operation; and

FIG. 13 is an explanatory diagram showing a condition within disk apparatus 2 until release of a secured area.

All or some drawings merely illustrate the outline for an illustrative purpose, and therefore, it should be noted that the drawings may not necessarily illustrate actual relative sizes, locations, etc., of the illustrated elements.

### BEST MODE FOR CARRYING OUT THE INVENTION

Preferred embodiments of a recording and reproducing apparatus and a recording and reproducing method according to the present invention will now be described with reference to the associated drawings.

### Embodiment 1

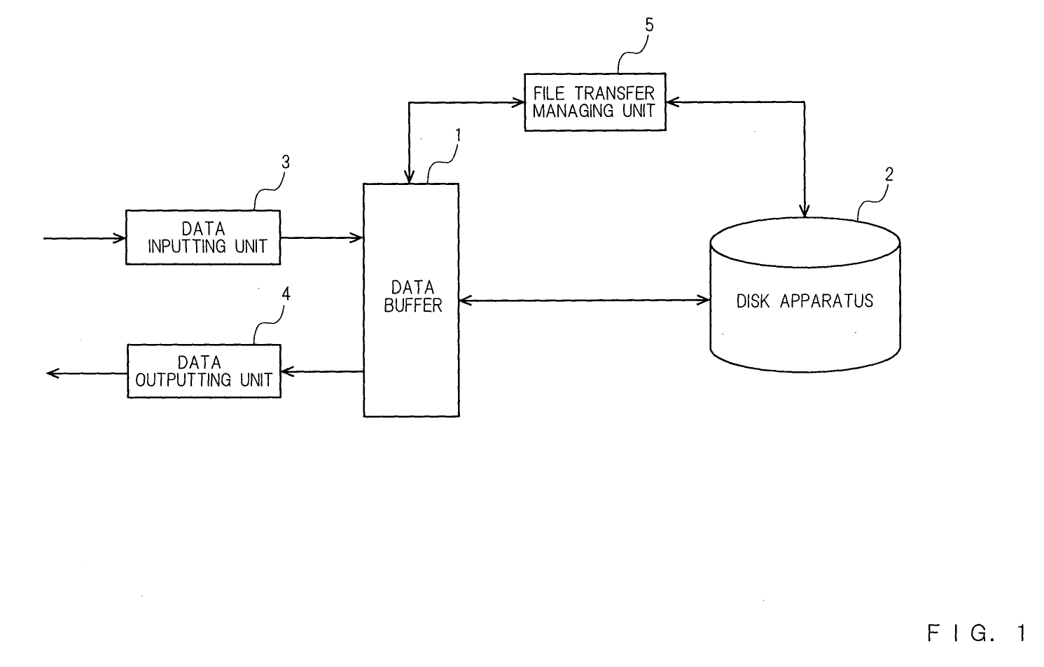

A recording and reproducing apparatus and a recording and reproducing method according to a preferred embodiment 1 of the present invention will now be described with reference to FIGS. 1 through 7.

FIG. 1 is a block diagram showing a structure of the recording and reproducing apparatus according to the preferred embodiment 1 of the present invention.

The apparatus according to the preferred embodiment 1 comprises a data buffer 1, a disk apparatus 2, a data inputting unit 3, a data outputting unit 4 and a file transfer managing unit 5.

The data buffer 1 is a buffer which is disposed between the data inputting unit 3, the data outputting unit 4 and the disk apparatus 2 and in which data are temporarily buffered during recording and reproducing operations.

The disk apparatus 2 is a non-volatile memory which stores data which are inputted and outputted during the recording and reproducing operations. In the preferred embodiment 1, the disk apparatus 2 is a disk apparatus (which is a DVD recording apparatus for instance) which can be removed.

The data inputting unit 3 transmits data inputted from outside during the recording operation to the data buffer 1.

The data outputting unit 4 receives reproduced data which are read from the disk apparatus 2 during the reproducing operation and buffered in the data buffer 1, and outputs the data to outside.

The file transfer managing unit 5 detects a fragmented file and searches for a free area within the disk apparatus 2 during the reproducing operation. When detecting a fragmented file as a result of the search, the file transfer managing unit 5 automatically moves the fragmented file to a continuous area within the disk apparatus 2 via the data buffer 1 in an attempt to defragment the fragmented file. Fragmented files are one chunk of files which are recorded scatteringly over a plurality of areas within the disk apparatus 2. Defragmenting fragmented file means to move the fragmented file via the data buffer 1 and re-record in one continuous area within the disk apparatus 2.

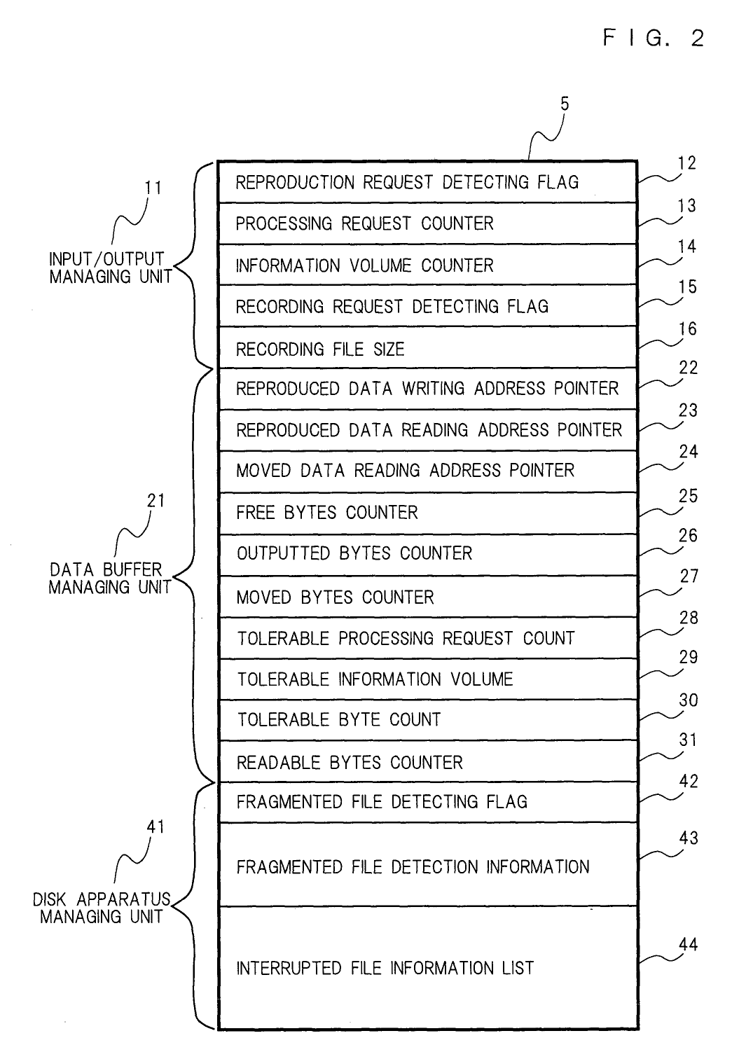

FIG. 2 shows an internal structure of the file transfer managing unit 5. The file transfer managing unit 5 comprises an input/output managing unit 11, a data buffer managing unit 21 and a disk apparatus managing unit 41. The input/output managing unit 11 comprises a reproduction request detecting flag 12, a processing request counter 13, an information volume counter 14, a recording request detecting flag 15 and a recorded file size 16, and manages an input/output condition during recording and reproduction.

The data buffer managing unit 21 comprises a reproduced data writing address pointer 22, a reproduced data reading address pointer 23, a moved data reading address pointer 24, a free bytes counter 25, outputted bytes counter 26, a moved bytes counter 27, a tolerable processing request count 28, a tolerable information volume 29, a tolerable byte count 30 and a readable bytes counter 31, and manages a state inside of the data buffer 1.

The disk apparatus managing unit 41 comprises a fragmented file detecting flag 42, fragmented file detection information 43 and an interrupted file information list 44, and manages a state within the disk apparatus 2.

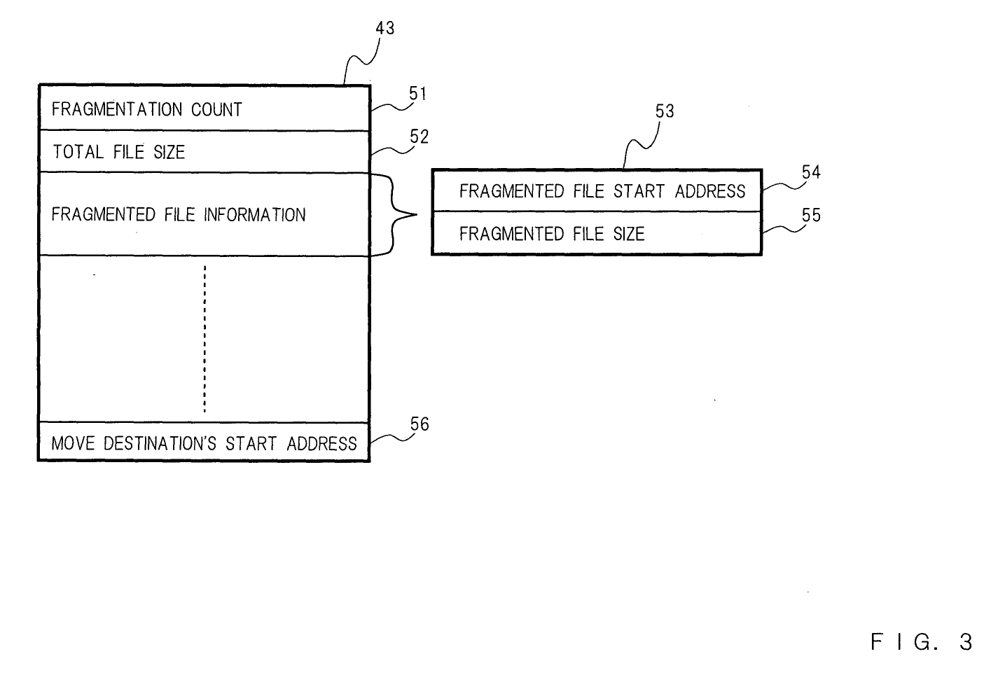

FIG. 3 is an explanatory diagram showing an internal structure of the fragmented file detection information 43. The fragmented file detection information 43 comprises a fragmentation count 51, a total file size 52, fragmented file information 53 and a move destination's start address 56. The fragmented file information 53 comprises a fragmented file start address 54 and a file fragment size 55, and its information count is equal to the fragmentation count 51. The fragmented file detection information 43 sets up information regarding a fragmented file which is stored in the disk apparatus 2 at the time of detection of file fragmentation.

As a new reproducing operation request is issued, the file transfer managing unit 5 checks a storage condition of a corresponding file to be reproduced which is stored in the disk apparatus 2. When it is recognized that this file is a fragmented file as a result of the check, the fragmented file detecting flag 42 is set to ON, the number of fragmented files is set as the fragmentation count 51, and the total size of the fragmented files is set as the total file size 52. As the fragmented file information 53, information regarding each fragmented file is set in the order of fragmentation for the number of the fragmented files. The start address of each fragmented file is set as the fragmented file start address 54, and the size of each fragmented file is set as the fragmented file size 55. In addition, a continuous area in which a free area exceeds the total file size 52 is searched within the disk apparatus 2, and the start address of the continuous area is set as the move destination's start address 56.

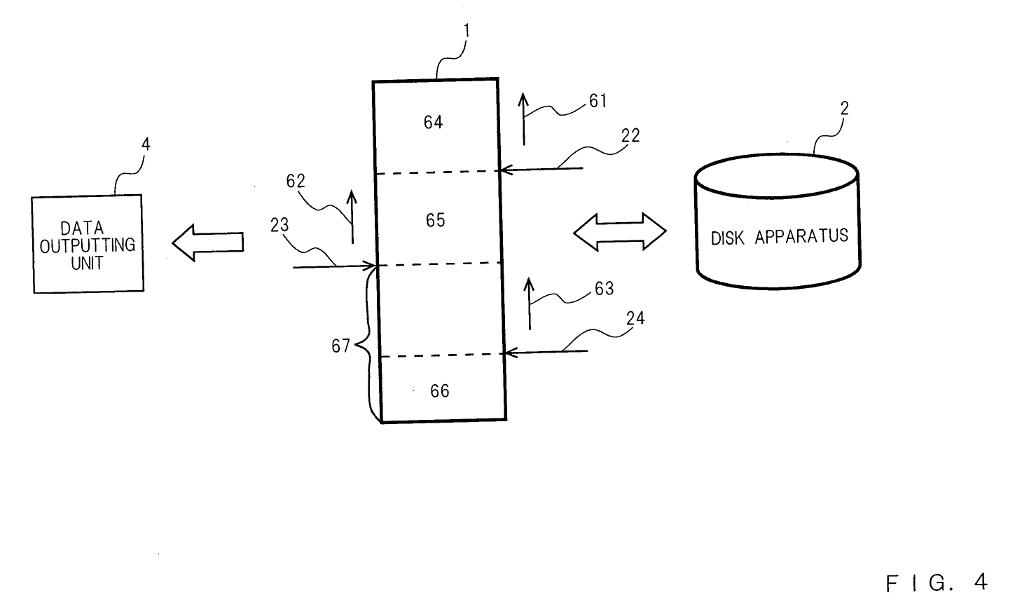

In the event that the file transfer managing unit 5 detects that the file to be reproduced is a fragmented file during the reproducing operation, the file transfer managing unit 5 buffers the data read from the disk apparatus 2 into the data buffer 1 and thereafter outputs the buffered data to the data outputting unit 4. Further, the file transfer managing unit 5 moves the file to the continuous area within the disk apparatus 2, so as to defragment the fragmented file. FIG. 4 shows a state within the data buffer 1 in such a situation.

The reproduced data writing address pointer 22 denotes an address at which data read from the disk apparatus 2 are buffered into the data buffer 1. A direction of reproduced data writing address pointer 61 expresses a direction in which an address is moved during writing. As the data read from the disk apparatus 2 are buffered, the reproduced data writing address pointer 22 is automatically updated toward the direction of reproduced data writing address pointer 61.

The reproduced data reading address pointer 23 denotes an address for transfer from the data buffer 1 to the data outputting unit 4. A direction of reproduced data reading address pointer 62 expresses a direction in which an address is moved during reading of data from the data buffer 1. As data are transferred from the data buffer 1 to the data outputting unit 4, the reproduced data reading address pointer 23 is automatically updated toward the direction of reproduced data reading address pointer 62.

The moved data reading address pointer 24 denotes an address for reading out data which are to be moved from the data buffer 1 to the disk apparatus 2 for defragmenting the fragmented file. A direction of moved data reading address pointer 63 expresses a direction in which an address is moved during reading of data from the data buffer 1. As data are moved, the moved data reading address pointer 24 is automatically updated toward the direction of moved data reading address pointer 63.

A free buffer area 64 is a free area which is not used within the data buffer 1. The free bytes counter 25 denotes a byte count of the free buffer area 64.

A readable data area 65 is an area within the data buffer 1 which stores such data which are read from the disk apparatus 2 and can be transferred to the data outputting unit 4.

The readable bytes counter 31 denotes a byte count of the readable data area 65. An outputted data area 67 is an area within the data buffer 1 which stores data whose transfer to the data outputting unit 4 has completed. The outputted bytes counter 26 denotes a byte count of the outputted data area 67. A moved data area 66 is an area which stores data whose transfer to the disk apparatus 2 from the data buffer 1 has completed. The moved bytes counter 27 denotes a byte count of the moved data area 66.

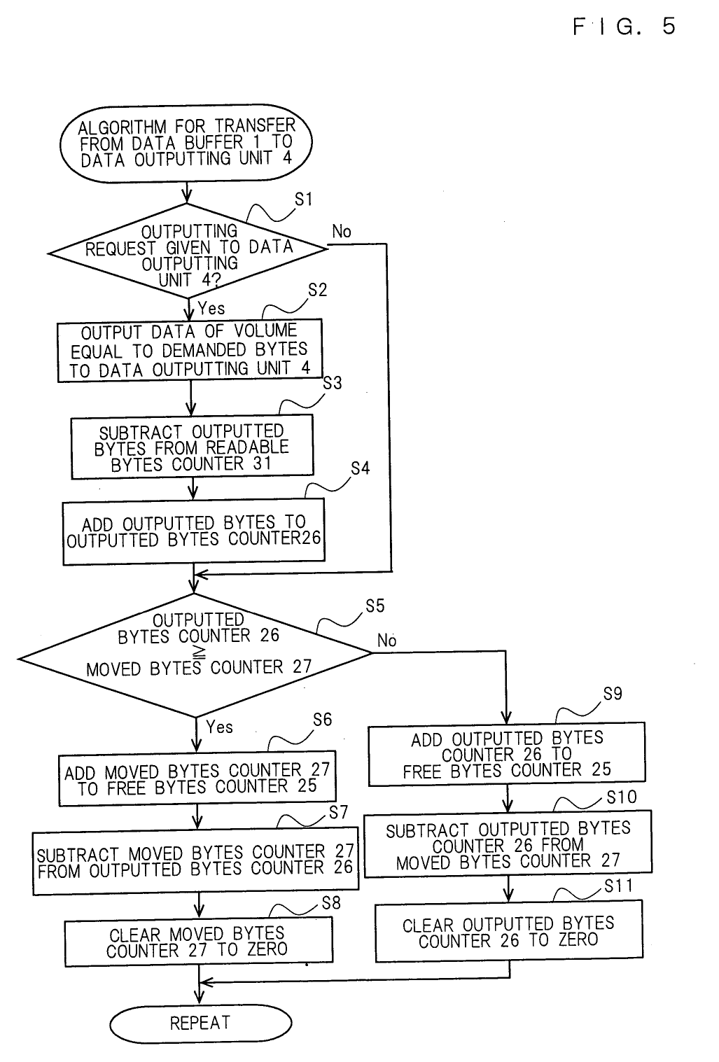

FIG. 5 is a flow chart showing an algorithm for data transfer from the data buffer 1 to the data outputting unit 4 during processing which is performed in the background during the reproducing operation to move a file for defragmenting the fragmented file.

At a step S1, whether there is a request for outputting to the data outputting unit 4 is determined. The sequence proceeds to a step S5 when there is not a request, whereas the sequence proceeds to a step S2 when there is a request.

At the step S2, demanded bytes of data are outputted from the data buffer 1 to the data outputting unit 4.

At a step S3, the outputted byte count is subtracted from the readable bytes counter 31.

At a step S4, the outputted byte count is added to the outputted bytes counter 26.

At the step S5, the outputted bytes counter 26 is compared with the moved bytes counter 27, and the sequence proceeds to a step S6 when the outputted bytes counter 26 is the same as or larger than the moved bytes counter 27 but to a step S9 when the moved bytes counter 27 is larger.

At the step S6, the count in the moved bytes counter 27 is added to the free bytes counter 25.

At a step S7, the count in the moved bytes counter 27 is subtracted from the outputted bytes counter 26.

At a step S8, the moved bytes counter 27 is cleared to zero.

The operations from the step S6 to the step S8 makes the moved data area 66 shown in FIG. 4 treated as a portion of the free buffer area 64.

At the step S9, the count in the outputted bytes counter 26 is added to the free bytes counter 25.

At a step S10, the count in the outputted bytes counter 26 is subtracted from the moved bytes counter 27.

At a step S11, the outputted bytes counter 26 is cleared to zero.

The operations from the step S9 to the step S11 makes the outputted data area 67 shown in FIG. 4 treated as a portion of the free buffer area 64.

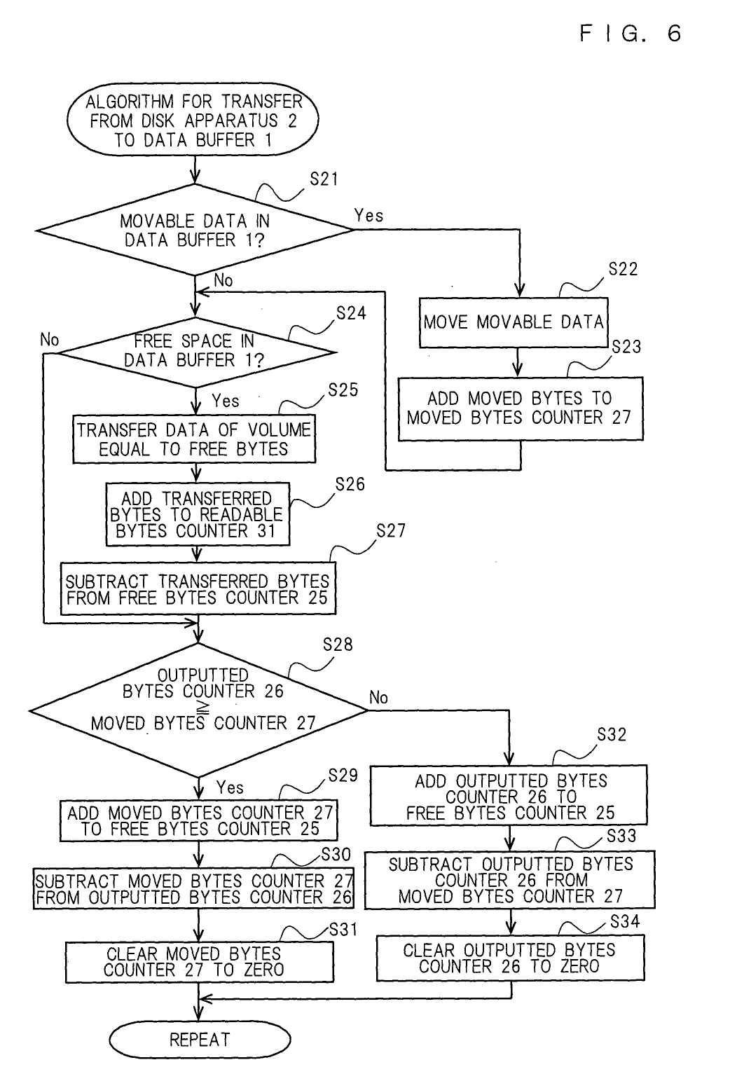

FIG. 6 is a flow chart showing an algorithm for an operation between the disk apparatus 2 and the data buffer 1 during processing which is performed by the file transfer managing unit 5 in the background during the reproducing operation to move a file for defragmenting the fragmented file.

At a step S21, whether there is a movable piece of data in the data buffer 1 is determined. The byte count of movable data is calculated by the following formula:

The byte count of movable data =the readable bytes counter 31+the outputted bytes counter 26−the moved bytes counter 27

The sequence proceeds to a step S24 when this formula yields zero (there is no movable piece of data), but to a step S22 when this formula yields other value than zero (there is a movable piece of data).

At the step S22, for defragmenting the fragmented file, the movable data are moved from the data buffer 1 to the disk apparatus 2. The movable pieces of data which form the fragmented file are recorded one after another in one continuous recording area within the disk apparatus 2.

At a step S23, the moved byte count is added to the moved bytes counter 27.

At the step S24, whether there is a free area within the data buffer 1 which can store data which will be transferred from the disk apparatus 2. The sequence proceeds to a step S28 when the free bytes counter 25 is zero (there is no such free area), but to a step S25 when the free bytes counter 25 has other value than zero (there is such a free area).

At the step S25, data are transferred to the free buffer area 64 within the data buffer 1 from the disk apparatus 2.

At a step S26, the transferred byte count is added to the readable bytes counter 31.

At a step S27, the transferred byte count is subtracted from the free bytes counter 25.

At the step S28, the outputted bytes counter 26 is compared with the moved bytes counter 27, and the sequence proceeds to a step S29 when the outputted bytes counter 26 is the same as or larger than the moved bytes counter 27 but to a step S32 when the moved bytes counter 27 is larger.

At the step S29, the count in the moved bytes counter 27 is added to the free bytes counter 25.

At a step S30, the count in the moved bytes counter 27 is subtracted from the outputted bytes counter 26.

At a step S31, the moved bytes counter 27 is cleared to zero.

The operations from the step S29 to the step S31 makes the moved data area 66 shown in FIG. 4 treated as a portion of the free buffer area 64.

At the step S32, the count in the outputted bytes counter 26 is added to the free bytes counter 25.

At a step S33, the count in the outputted bytes counter 26 is subtracted from the moved bytes counter 27.

At a step S34, the outputted bytes counter 26 is cleared to zero.

The operations from the step S32 to the step S34 makes the outputted data area 67 shown in FIG. 4 treated as a portion of the free buffer area 64.

Such management of the data buffered in the data buffer 1 prohibits the buffered data from getting overwritten until a file has been moved for defragmenting the fragmented file, thereby making it possible to output data to the data outputting unit 4 and move the file to the continuous area within the disk apparatus 2.

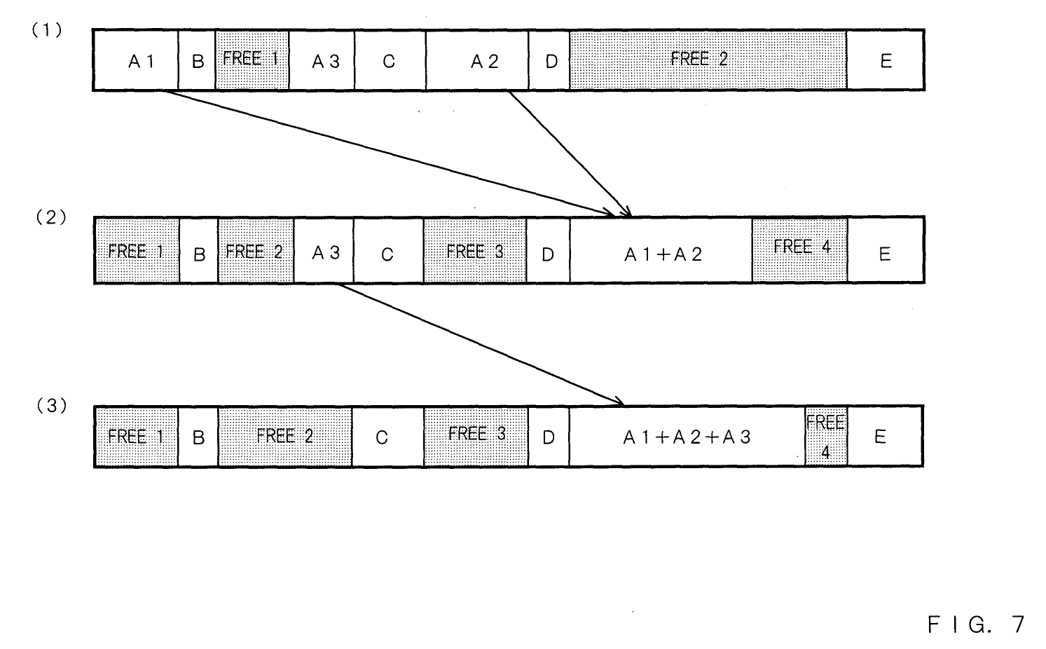

FIG. 7 is an explanatory diagram for describing processes of moving a file during file moving processing for defragmenting the fragmented file until a fragmented file within the disk apparatus 2 has been moved to a continuous area within the disk apparatus 2.

Files A1, A2 and A3 in the section (1) are fragmented files of a file A, while denoted at B, C, D and E are other files. FREE 1 and FREE 2 are free areas in which a file can be stored. Assume now that the FREE 2 area is larger than the capacity of the file A (A1+A2+A3).

The section (2) illustrates a condition that Al and A2 have been moved to FREE 2 which is shown in the section (1).

The section (3) illustrates a condition that A3 has been moved FREE 4 which is shown in the section (2), the file A has accordingly been stored in a continuous area and fragmentation has been therefore eliminated.

For defragmenting the fragmented file, (A) it is necessary to perform processing of reading the fragmented file from the disk apparatus 2 and buffer the same into the data buffer 1, and (B) it is necessary to perform processing of writing the data buffered in the data buffer 1 into the disk apparatus 2.

In the case of the recording and reproducing apparatus according to the preferred embodiment 1 which defragments a fragmented file (data being reproduced) during reproduction based on an instruction from a user, a fragmented file is buffered already in the data buffer 1. Hence, execution of the processing (B) above alone is necessary for defragmenting the fragmented file. A load upon the recording and reproducing apparatus is therefore lower than where it is required to execute all of an operation based on a user's instruction, the processing (A) described above and the processing (B) described above. In the preferred embodiment 1, as long as the recording and reproducing apparatus has a capability of executing other processing during reproduction, it is possible to automatically defragment fragmented files on the disk apparatus 2 utilizing this extra capability.

### Embodiment 2

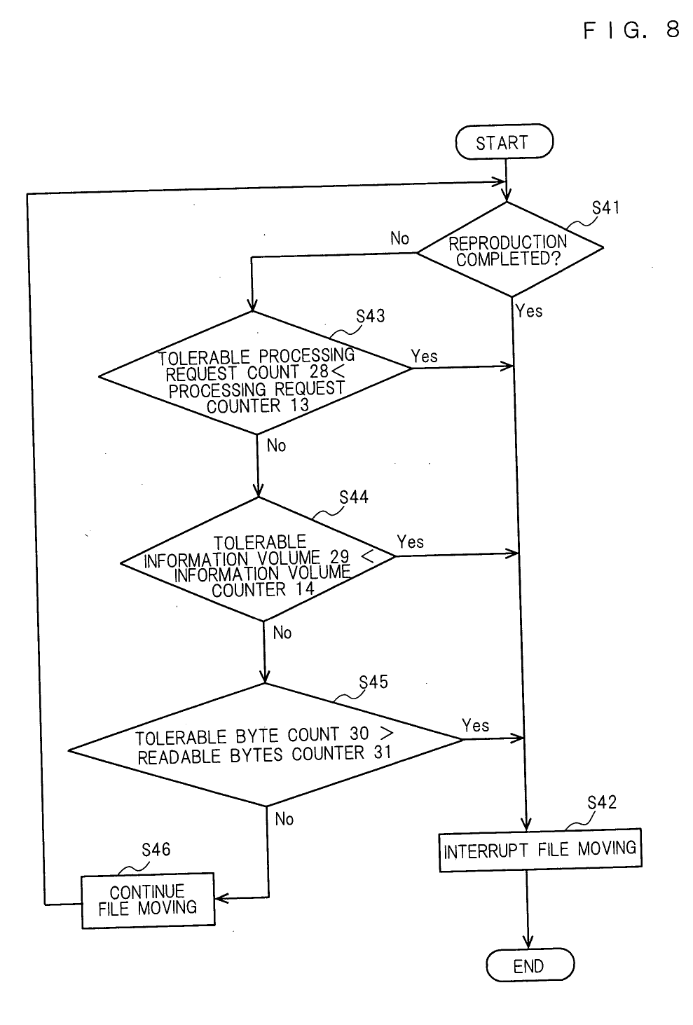

A recording and reproducing apparatus and a recording and reproducing method according to a preferred embodiment 2 of the present invention will now be described with reference to FIG. 8.

FIG. 8 is a flow chart showing an algorithm for an operation performed by the file transfer managing unit 5 to interrupt file moving processing for defragmenting the fragmented file upon satisfaction of a designated condition during processing which is performed in the background during the reproducing operation in order to move a fragmented file for defragmenting it.

At a step S41, whether reproduction has completed is determined. The reproduction request detecting flag 12 is a flag which is set to ON during the reproducing operation, and it is determined that reproduction has completed and the sequence proceeds to a step S42 when this flag is not ON. When this flag is ON, the sequence proceeds to a step S43.

At the step S42, processing to interrupt file moving for defragmenting the fragmented file is executed.

At a step S43, the tolerable processing request count 28 is compared with the processing request counter 13. The sequence proceeds to the step S42 when the processing request counter 13 is found to exceed the tolerable processing request count 28 as a result of the comparison. When the processing request counter 13 is the same or smaller than the tolerable processing request count 28, the sequence proceeds to a step S44. Set as the tolerable processing request count 28 is the number of processing which can be performed by this recording and reproducing apparatus which treats each one of recording processing, reproduction processing and file moving processing for defragmenting the fragmented file as one processing. The processing request counter 13 counts the total number of processing requests which are being currently executed.

At the step S44, the tolerable information volume 29 is compared with the information volume counter 14. The sequence proceeds to the step S42 when the information volume counter 14 is found to exceed the tolerable information volume 29. When the information volume counter 14 is the same as or smaller than the tolerable information volume 2, the sequence proceeds to a step S45. Set as the tolerable information volume 29 is the volume of information which can be transferred in the disk apparatus 2. The information volume counter 14 counts the volume of information for each one of the processing requests which are being currently executed.

At a step S45, the tolerable byte count 30 is compared with the readable bytes counter 31. The sequence proceeds to the step S42 when the tolerable byte count 30 is found to exceed the readable bytes counter 31. The sequence proceeds to a step S46 when the tolerable byte count 30 is the same as or smaller than the readable bytes counter 31. Set to the tolerable byte count 30 is a data byte count of a minimum volume of read data which needs be buffered in the data buffer 1 to continue the ongoing reproducing operation without a break.

In this manner, it is possible to interrupt the file moving processing for defragmenting the fragmented file in accordance with a condition which corresponds to a status regarding a recording and reproducing request, buffering and the like and a change in transfer information volume. This further makes it possible to move a file for defragmenting the fragmented file in an environment wherein a transfer processing capability of mainly the disk apparatus 2 is sufficiently utilized. It is possible to select these methods described above in accordance with specifications, and in some cases, combine a plurality of conditions.

### Embodiment 3

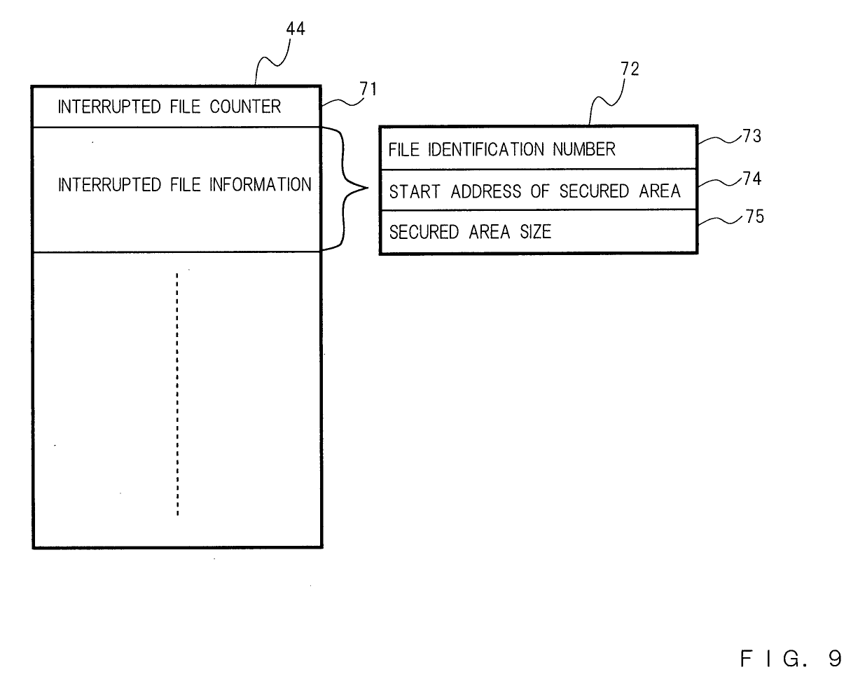

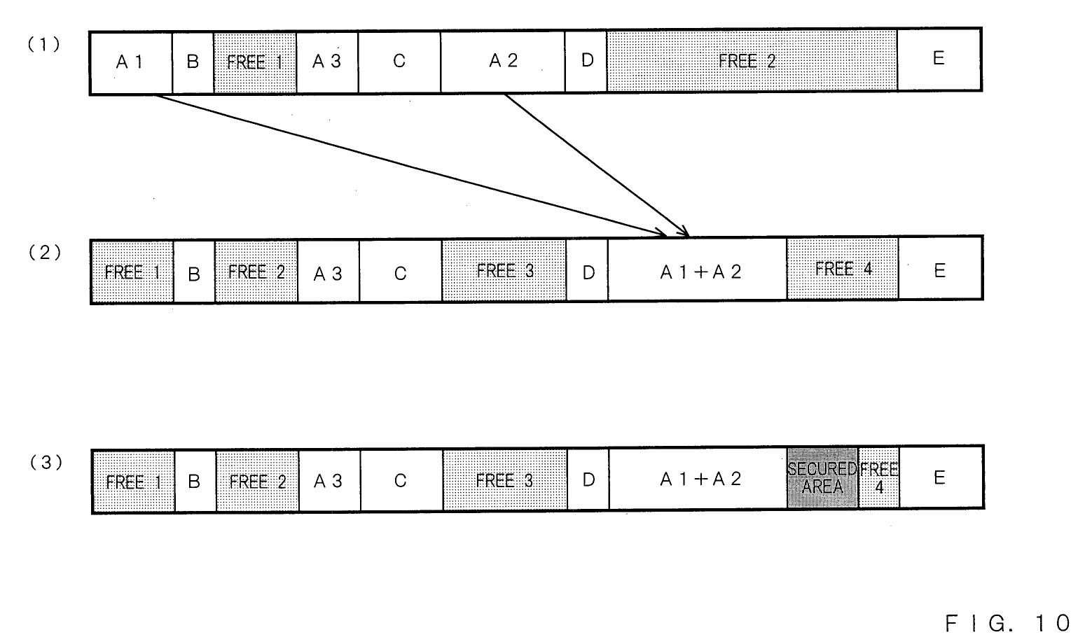

A recording and reproducing apparatus and a recording and reproducing method according to a preferred embodiment 3 of the present invention will now be described with reference to FIGS. 9 through 10.

FIG. 9 shows a structure of the interrupted file information list 44 which holds information regarding all interrupted files during file moving interruption processing for defragmenting the fragmented file at the step S42 which is shown in FIG. 8. The interrupted file information list 44 holds information regarding all interrupted files within the disk apparatus 2 for which file moving for defragmenting the fragmented file has been interrupted. Set in an interrupted file counter 71 is the number of fragmented files for which file moving for defragmenting the fragmented file is currently in a halt. Interrupted file information 72 comprises a file identification number 73, a start address of secured area 74 and a secured area size 75. Set as the file identification number 73 is the identification number of a fragmented file for which file moving for defragmenting the fragmented file has been interrupted. This number is assigned uniquely to each file within the disk apparatus 2. Set as the start address of secured area 74 is the start address of one continuous free area which includes a recording area whose capacity covers fragmented files which have not been moved yet. The byte count of a secured free area is set as the secured area size 75. There are the same number of the interrupted file information 72 as the count of the interrupted file counter 71.

FIG. 10 shows processes of a file arrangement within the disk apparatus 2 since file moving for defragmenting the fragmented file until interruption.

Files A1, A2 and A3 in the section (1) are fragmented files of a file A, while denoted at B, C, D and E are other files. FREE 1 and FREE 2 are free areas in which a file can be stored. Assume now that the FREE 2 area is larger than the capacity of the file A (A1+A2+A3).

The section (2) illustrates a condition that A1 and A2 have been moved to FREE 2 which is shown in the section (1).

The section (3) illustrates a condition that file moving interruption processing occurred after moving has completed as the section (2) and a recording area whose size is equivalent to the capacity of A3 is accordingly secured in the FREE 3 area.

As described above, since a continuous area is secured at the time that it becomes possible to resume file moving for defragmenting the fragmented file by securing a continuous area, as those portions for which file moving has not been completed yet are moved to a secured area, file moving for defragmenting the fragmented file completes. Further, with the continuous area secured, it is possible to prevent occurrence of a new fragmented file which would be otherwise created upon recording of a different file in the same area.

### Embodiment 4

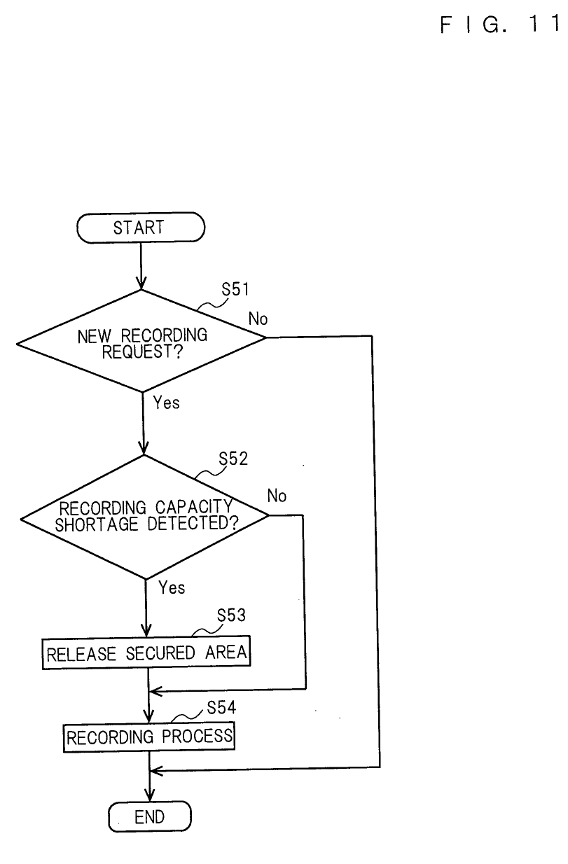

A recording and reproducing apparatus and a recording and reproducing method according to a preferred embodiment 4 of the present invention will now be described with reference to FIGS. 11 through 13.

FIG. 11 is a flow chart showing an algorithm for an operation which the file transfer managing unit 5 performs to release a secured area for resumption of file moving for defragmenting the fragmented file upon detection of a recording capacity shortage in response to a new recording request.

At a step S51, whether there is a new recording request is determined. The recording request detecting flag 15 is a flag which is set to ON when there is a new recording request, and it is therefore determined that there is a new recording request and the sequence proceeds to a step S52 when this flag is ON but this processing is terminated when this flag is not ON.

At the step S52, a free area is searched for within the disk apparatus 2 and whether there is a free area having a recording file size of 16 or larger is determined. A file size (byte count) to newly record in accordance with a new recording request is set as the recording file size 16. When the free area is smaller than the recording file size 16, the sequence proceeds to a step S53, whereas the sequence proceeds to a step S54 the free area is the same as or larger than the recording file size 16.

At the step S53, the area secured for resumption of file moving for defragmenting the fragmented file (for instance, a secured area shown in (3) in FIG. 10) is released. This allows to record a file in the released area.

At the step S54, a file is recorded.

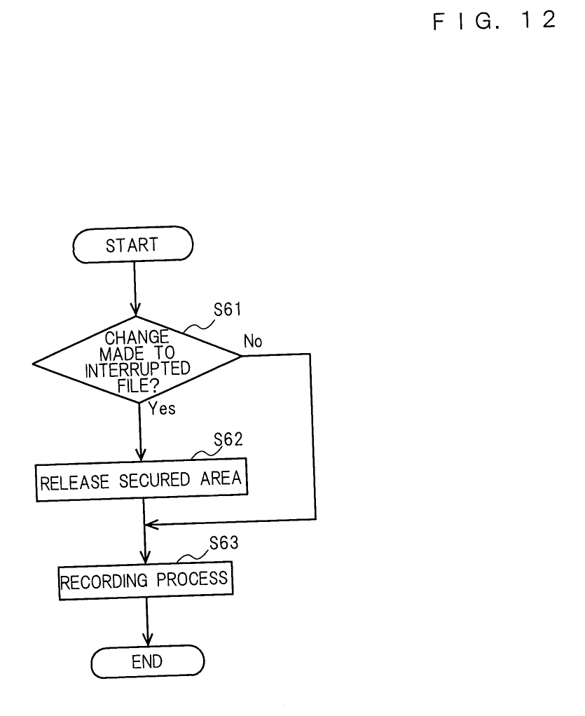

FIG. 12 is a flow chart showing an algorithm for an operation which the file transfer managing unit 5 performs to release a secured area for resumption of file moving for defragmenting the fragmented file upon detection of a change made to a file for which file moving for defragmenting the fragmented file has been interrupted.

At a step S61, whether there is a change made to a file for which file moving for defragmenting the fragmented file has been interrupted is determined. The sequence proceeds to a step S62 when there is a change made to the file, but a step S63 when there is not a change made to the file.

At the step S62, an area secured for resumption of file moving processing for defragmenting the fragmented file (for example, the secured area shown in the section (3) in FIG. 10) is released. This makes it possible to record a file in the released area.

At the step S63, a file is recorded.

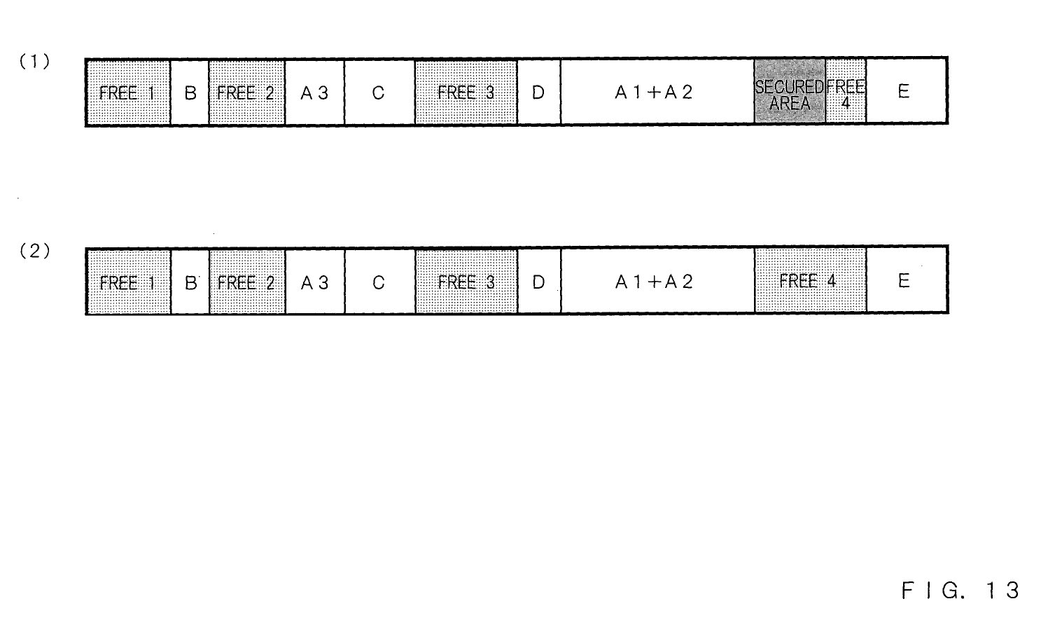

FIG. 13 shows a storage condition of a file within the disk apparatus 2 for which file moving processing for defragmenting the fragmented file is in a halt and a condition as it is after release of the secured area.

Like the section (3) in FIG. 10, the section (1) represents a condition that an area whose size is the same as that of the fragmented file A3 which has not been moved yet is secured after and continuous to an A1+A2 area.

The section (2) represents a condition that the area secured for the file A is released and integrated with FREE 4 which is shown in the section (1).

Thus, as a secured area is released appropriately, it is possible to respond to a recording request without any disturbance.

As described above, the recording and reproducing apparatus and the recording and reproducing method according to the present invention require to execute the file moving processing for defragmenting the fragmented file in the background of reproduction. Hence, it is possible to maintain a disk medium always in a stable state with less file fragmentation without forcing a burden upon a user.

In addition, as a continuous area is secured in advance in the event that the defragment processing is interrupted, it is possible to prevent acceleration of the processing and occurrence of new fragmentation upon resumption of the file defragment processing. Further, since the defragment processing is interrupted appropriately or a secured area is released, normal recording and reproducing processing is not disturbed.

While the foregoing has described the present invention in relation to preferred embodiments in certain details, the detailed structures according to the preferred embodiments described above may be modified. Combinations and an order of the respective elements may be modified without deviating from the scope-of claims and the spirit of the invention.

### INDUSTRIAL APPLICABILITY

The present invention is used as a recording apparatus for recording information of a video signal or an audio signal, a reproducing apparatus for the same, and a recording method and a reproducing method for the same.

1. A recording and reproducing apparatus for recording and reproducing a video signal or an audio signal, characterized in comprising:
a disk apparatus which stores data as a file;
a data buffer which temporarily holds data read out from said disk apparatus;
a data outputting unit which outputs data read out from said data buffer; and
a file transfer managing unit which detects a fragmented file from among files which are stored in said disk apparatus, checks a state of a free area within said disk apparatus, and moves said file using said data buffer such that said fragmented file will be defragmented, wherein
when said file transfer managing unit detects fragmentation of a file to be reproduced during reproduction, said file transfer managing unit automatically moves said fragmented file such that said file will be defragmented.

2. The recording and reproducing apparatus for recording and reproducing a video signal or an audio signal of claim 1, characterized in that during reproduction, said file transfer managing unit ensures that a file which is held in said data buffer for reproduction and which is to be moved will not be overwritten until said file has been moved.

3. The recording and reproducing apparatus for recording and reproducing a video signal or an audio signal of claim 1 or 2, characterized in that upon stop of reproduction, said file transfer managing unit interrupts file moving for defragmenting the fragmented file.

4. The recording and reproducing apparatus for recording and reproducing a video signal or an audio signal of claim 1, characterized in that said disk apparatus is a disk apparatus which can be removed from said recording and reproducing apparatus.

5. The recording and reproducing apparatus for recording and reproducing a video signal or an audio signal of claim 1, characterized in that said file transfer managing unit monitors the number of processing requests for recording or reproduction, and when the number of said processing requests exceeds a certain number, said file transfer managing unit interrupts file moving for defragmenting the fragmented file.

6. The recording and reproducing apparatus for recording and reproducing a video signal or an audio signal of claim 1, characterized in that said file transfer managing unit monitors an information volume of processing requests for recording or reproduction, and when the information volume of said processing requests which have not been executed yet exceeds a certain value, said file transfer managing unit interrupts file moving for defragmenting the fragmented file.

7. The recording and reproducing apparatus for recording and reproducing a video signal or an audio signal of claim 1, characterized in that said file transfer managing unit monitors a byte count of readable byte buffered in the data buffer, and when said byte count of readable byte is smaller than a certain count, said file transfer managing unit interrupts file moving for defragmenting the fragmented file.

8. The recording and reproducing apparatus for recording and reproducing a video signal or an audio signal of claim 1, characterized in that when file moving for defragmenting the fragmented file is interrupted, said file transfer managing unit secures on the disk apparatus a free area which is necessary for defragmenting the fragmented file in relation to said file such that said secured area will not be used during recording.

9. The recording and reproducing apparatus for recording and reproducing a video signal or an audio signal of claim 8, characterized in that said file transfer managing unit releases said secured area upon issuance of a new recording request and detection of a shortage of a demanded recording area.

10. The recording and reproducing apparatus for recording and reproducing a video signal or an audio signal of claim 8, characterized in that said file transfer managing unit detects a change made to a file which is associated with said secured area and releases said secured area.

11. A recording and reproducing method of recording and reproducing a video signal or an audio signal, characterized in comprising:
a step of inputting a reproduction instruction;
a reading step of reading data which are stored as a file in a disk apparatus;
a buffering step of holding read data in a data buffer;
a data outputting step of outputting data read out from said data buffer; and
a defragmenting step of, upon detection of a fragmented file from among files which are stored in said data buffer, automatically moving said file such that said fragmented file will be defragmented.

12. The recording and reproducing method of recording and reproducing a video signal or an audio signal of claim 11, characterized in comprising a step of ensuring that a file which is held in said data buffer for reproduction and which is to be moved will not be overwritten until said file has been moved during reproduction.

13. The recording and reproducing method of recording and reproducing a video signal or an audio signal of claim 11, characterized in comprising a step at which upon stop of reproduction, said file transfer managing unit interrupts file moving for defragmenting the fragmented file.

14. The recording and reproducing method of recording and reproducing a video signal or an audio signal of claim 11, characterized in comprising a step of monitoring the number of processing requests for recording or reproduction, and interrupting file moving for defragmenting the fragmented file when the number of said processing requests exceeds a certain number.

15. The recording and reproducing method of recording and reproducing a video signal or an audio signal of claim 11, characterized in comprising a step of monitoring an information volume of processing requests for recording or reproduction, and interrupting file moving for defragmenting the fragmented file when the information volume of said processing requests which have not been executed yet exceeds a certain value.

16. The recording and reproducing method of recording and reproducing a video signal or an audio signal of claim 11, characterized in comprising a step of monitoring a byte count of readable byte buffered in the data buffer, and interrupting file moving for defragmenting the fragmented file when said byte count of readable byte is smaller than a certain count.

17. The recording and reproducing method of recording and reproducing a video signal or an audio signal of claim 11, characterized in comprising a step of securing on the disk apparatus a free area which is necessary for defragmenting fragmented file in relation to said file when file moving for defragmenting the fragmented file is interrupted, such that said secured area will not be used during recording.

18. The recording and reproducing method of recording and reproducing a video signal or an audio signal of claim 17, characterized in comprising a step of releasing said secured area upon issuance of a new recording request and detection of a shortage of a demanded recording area.

19. The recording and reproducing method of recording and reproducing a video signal or an audio signal of claim 17, characterized in comprising a step of detecting a change made to a file which is associated with said secured area and releasing said secured area.
